(19) United States
(12) Patent Application Publication
(10) Pub. No.: US 2014/0335287 A1
(43) Pub. Date: Nov. 13, 2014

(54) ATOMIC LAYER DEPOSITION APPARATUS AND ATOMIC LAYER DEPOSITION METHOD

(71) Applicant: Sony Corporation, Tokyo (JP)

(72) Inventors: Hiroyuki NAGAI, Kanagawa (JP); Tetsuro KUWAYAMA, Tokyo (JP)

(73) Assignee: Sony Corporation, Tokyo (JP)

(21) Appl. No.: 14/264,840

(22) Filed: Apr. 29, 2014

(30) Foreign Application Priority Data
May 9, 2013 (JP) 2013-099016

(51) Int. Cl. H01J 37/32; C23C 16/455

(52) U.S. Cl. CPC H01J 37/3244; C23C 16/45525; C23C 16/45544
USPC 427/569; 118/733; 118/723 R; 427/248.1

(57) ABSTRACT

Provided is an atomic layer deposition apparatus including: a sealable deposition chamber; a holding portion configured to hold a substrate including a deposition surface in the deposition chamber; a supply mechanism that includes an introduction portion connected to a gas supply source that supplies gas and is configured to supply gas introduced into the introduction portion to the deposition chamber from a position opposing the deposition surface; and an exhaust mechanism that includes an exhaust portion connected to an exhaust mechanism capable of exhausting gas and is configured to exhaust the deposition chamber from a position opposing the deposition surface.

### CROSS REFERENCES TO RELATED APPLICATIONS

The present application claims priority to Japanese Priority Patent Application JP 2013-099016 filed in the Japan Patent Office on May 9, 2013, the entire content of which is hereby incorporated by reference.

### BACKGROUND

The present disclosure relates to an atomic layer deposition (ALD) apparatus capable of forming a thin film on a substrate and an atomic layer deposition method.

In recent years, as a thin film production method in a production field of large glass substrates (e.g., substrate used in flat panel display (FPD), solar panel, etc.), an atomic layer deposition (ALD) method is attracting attention. The ALD method involves supplying two types of precursor gas alternately on a deposition surface of a substrate to form one layer of a target substance at a time on the deposition surface of the substrate. The ALD method is excellent in controllability regarding a film thickness of a thin film, and a thin film of a high quality can thus be formed.

Japanese Patent Application Laid-open No. 2006-310813 (hereinafter, referred to as Patent Document 1) discloses an ALD apparatus. In the ALD apparatus, an introduction portion for introducing precursor gas into a deposition chamber is provided at one end portion on a deposition surface of a substrate, and an exhaust portion for exhausting the deposition chamber is provided at the other end portion opposing the one end portion on the deposition surface of the substrate. The precursor gas introduced into the deposition chamber is supplied to the deposition surface of the substrate, and surplus gas that has passed the deposition surface of the substrate is exhausted. Therefore, the two types of precursor gas are alternately introduced into the deposition chamber and alternately supplied to the deposition surface of the substrate after that. As a result, a thin film is formed on the deposition surface of the substrate.

### SUMMARY

In the ALD apparatus disclosed in Patent Document 1, a concentration of the gas on the deposition surface of the substrate becomes non-uniform on the introduction portion side and the exhaust portion side. Therefore, it is difficult to uniformly control a gas supply condition across the entire area of the deposition surface of the substrate. Consequently, in the ALD apparatus, the film thickness and quality of a thin film formed on the deposition surface of the substrate are apt to become non-uniform.

In view of the circumstances as described above, there is a need for an atomic layer deposition apparatus capable of forming a uniform thin film.

According to an embodiment of the present disclosure, there is provided an atomic layer deposition apparatus including a deposition chamber, a holding portion, a supply mechanism, and an exhaust mechanism.

The deposition chamber is sealable.

The holding portion is configured to hold a substrate including a deposition surface in the deposition chamber.

The supply mechanism includes an introduction portion connected to a gas supply source that supplies gas and is configured to supply gas introduced into the introduction portion to the deposition chamber from a position opposing the deposition surface.

The exhaust mechanism includes an exhaust portion connected to an exhaust mechanism capable of exhausting gas and is configured to exhaust the deposition chamber from a position opposing the deposition surface.

With this structure, it becomes possible to perform gas introduction and exhaust with respect to the deposition chamber at a position opposing the deposition surface of the substrate. Therefore, in the atomic layer deposition apparatus, gas is uniformly supplied to the entire deposition surface of the substrate, and the gas concentration on the deposition surface of the substrate hardly becomes non-uniform. Accordingly, the atomic layer deposition apparatus can form a uniform thin film on the deposition surface of the substrate.

Moreover, in the atomic layer deposition apparatus, even when the area opposing the deposition surface of the substrate is narrowed, the gas concentration on the deposition surface of the substrate hardly becomes non-uniform. Therefore, the volume of the deposition chamber can be reduced. As a result, in the atomic layer deposition apparatus, an exhaust time can be shortened.

The supply mechanism may further include a supply port that is connected to the introduction portion and opposes the deposition surface.

In this case, the exhaust mechanism may further include an exhaust port that is connected to the exhaust portion and opposes the deposition surface.

With this structure, the supply mechanism and the exhaust mechanism can be controlled independently.

The supply port and the exhaust port may be adjacent to each other.

With this structure, the gas introduction and exhaust are performed at adjacent positions. Therefore, in the atomic layer deposition apparatus, the gas concentration on the deposition surface of the substrate hardly becomes non-uniform.

The supply mechanism may further include a plurality of supply ports and a supply path that connects the plurality of supply ports to the introduction portion and forms a manifold with the plurality of supply ports.

Further, the exhaust mechanism may further include a plurality of exhaust ports and an exhaust path that connects the plurality of exhaust ports to the exhaust portion and forms a manifold with the plurality of exhaust ports.

With this structure, since the supply path and the plurality of supply ports form a manifold, the gas pressure in the supply path becomes constant, and the gas introduction pressure at the plurality of supply ports with respect to the deposition chamber also becomes constant. Moreover, since the exhaust path and the plurality of exhaust ports form a manifold, the gas pressure in the exhaust path becomes constant, and the gas exhaust pressure at the plurality of exhaust ports with respect to the deposition chamber also becomes constant. As a result, in the atomic layer deposition apparatus, the gas concentration on the deposition surface of the substrate hardly becomes non-uniform.

The supply path, the supply ports, the exhaust path, and the exhaust ports may all formed on a single flow path formation member.

With this structure, the function described above can be realized with ease.

The atomic layer deposition apparatus may further include a plurality of supply mechanisms.

In this case, the plurality of supply mechanisms may supply different types of gas to the deposition chamber.

With this structure, the supply mechanism can be used distinguishably depending on the type of precursor gas. As a result, crosstalk among the precursor gas can be prevented from occurring in the supply mechanism. Thus, with this structure, the precursor gas can be prevented from being used wastefully, and a precipitation of a reacting substance in the supply mechanism can be prevented from occurring.

The supply mechanism may further include a plurality of supply paths and an introduction chamber that connects the plurality of supply paths to the introduction portion and forms a manifold with the plurality of supply paths.

Further, the exhaust mechanism may further include a plurality of exhaust paths and an exhaust chamber that connects the plurality of exhaust paths to the exhaust portion and forms a manifold with the plurality of exhaust paths.

With this structure, since the introduction chamber and the plurality of supply paths form a manifold, the gas pressure in the introduction chamber becomes constant, and the gas pressure at the plurality of supply paths also becomes constant. Moreover, since the exhaust chamber and the plurality of exhaust paths form a manifold, the gas pressure in the exhaust chamber becomes constant, and the gas pressure at the plurality of exhaust paths also becomes constant.

Therefore, the gas introduction pressure at all the supply ports with respect to the deposition chamber becomes constant, and the gas exhaust pressure in the deposition chamber at all the exhaust ports becomes constant. Therefore, in the atomic layer deposition apparatus, the gas concentration on the deposition surface of the substrate hardly becomes non-uniform.

The plurality of supply paths and the plurality of exhaust paths may be arranged alternately.

With this structure, a structure in which the plurality of supply ports and the plurality of exhaust ports are close to one another can be realized.

The atomic layer deposition apparatus may further include a bypass path that connects the exhaust mechanism and the introduction portion.

With this structure, exhaust of the deposition chamber by the exhaust mechanism can be performed via the introduction portion in addition to the exhaust portion. Accordingly, the exhaust time of the deposition chamber can be shortened.

The atomic layer deposition apparatus may further include a plasma unit that is provided between the gas supply source and the introduction portion and causes plasma of the gas to be introduced into the introduction portion.

With this structure, precursor gas activated by plasma is supplied to the deposition surface of the substrate. Therefore, reactions of the precursor gas are activated.

The atomic layer deposition apparatus may further include a pair of electrodes that are provided inside the deposition chamber and connected to a power supply to cause plasma of the gas in the deposition chamber.

With this structure, plasma of the precursor gas can be generated in the deposition chamber. Therefore, reactions of the precursor gas are activated.

The exhaust mechanism and the supply mechanism may both be formed on a single flow path formation member, and the holding portion and the flow path formation member may constitute the pair of electrodes.

With this structure, a structure capable of activating reactions of the precursor gas in the deposition chamber can be realized with ease.

The atomic layer deposition apparatus may further include a plurality of atomic layer deposition units each including the deposition chamber, the holding portion, the supply mechanism, and the exhaust mechanism.

With this structure, thin films can be formed on the deposition surface of the plurality of substrates at the same time.

The plurality of atomic layer deposition units may be laminated in a direction vertical to the deposition surface.

With this structure, the atomic layer deposition apparatus becomes a multilayer structure. As a result, it becomes possible to miniaturize the atomic layer deposition apparatus and commonly set carry-in and carry-out directions of the substrates in the atomic layer deposition units.

According to an embodiment of the present disclosure, there is provided an atomic layer deposition method including: supplying gas from a first position opposing a deposition surface of a substrate; and exhausting from a second position opposing the deposition surface.

With this structure, the gas introduction and exhaust with respect to the deposition chamber are performed at positions opposing the deposition surface of the substrate. Therefore, by the atomic layer deposition method, gas is apt to be supplied uniformly across the entire deposition surface of the substrate, and the gas concentration on the deposition surface of the substrate hardly becomes non-uniform. Therefore, with the atomic layer deposition method, a uniform thin film can be formed on the deposition surface of the substrate.

The first position and the second position may be adjacent to each other.

With this structure, the gas introduction and exhaust are performed at close positions. Therefore, in the atomic layer deposition method, the gas concentration on the deposition surface of the substrate hardly becomes non-uniform.

The atomic layer deposition method may further include: supplying gas from a plurality of first positions; and exhausting from a plurality of second positions.

With this structure, the gas concentration on the deposition surface of the substrate becomes more uniform.

The atomic layer deposition method may further include supplying gas activated by plasma from the first position.

With this structure, the precursor gas activated by plasma is supplied to the deposition surface of the substrate. Therefore, reactions of the precursor gas are activated.

The atomic layer deposition method may further include causing plasma of the gas supplied from the first position by applying a voltage between the deposition surface and a surface opposing the deposition surface.

With this structure, plasma of the precursor gas supplied to the deposition surface can be generated. Therefore, reactions of the precursor gas are activated.

As described above, according to the embodiments of the present disclosure, an atomic layer deposition apparatus and an atomic layer deposition method with which a uniform thin film can be formed can be provided.

These and other objects, features and advantages of the present disclosure will become more apparent in light of the following detailed description of best mode embodiments thereof, as illustrated in the accompanying drawings.

Additional features and advantages are described herein, and will be apparent from the following Detailed Description and the figures.

### BRIEF DESCRIPTION OF THE FIGURES

FIG. 1A is a plan view of an ALD apparatus according to an embodiment of the present disclosure;

FIG. 1B is a schematic diagram showing an internal structure of the ALD apparatus shown in FIG. 1A;

FIG. 2 is a cross-sectional diagram taken along the line A-A′ of the ALD apparatus shown in FIG. 1A;

FIG. 3 is a cross-sectional diagram taken along the line B-B′ of the ALD apparatus shown in FIG. 1A;

FIG. 4 is a flowchart showing a deposition method for the ALD apparatus shown in FIG. 1A;

FIG. 5 is an explanatory diagram of a modified example of the ALD apparatus shown in FIG. 1A;

FIG. 6 is a diagram exemplifying a size of each portion of the ALD apparatus shown in FIG. 1A;

FIG. 7 is a diagram showing a modified example of the ALD apparatus shown in FIG. 5;

FIG. 8 is a cross-sectional diagram of a multilayer ALD apparatus according to an embodiment of the present disclosure;

FIG. 9 is a diagram showing a gas supply system and an exhaust system of the multilayer ALD apparatus shown in FIG. 8;

FIG. 10 is a diagram showing a gas supply system and an exhaust system of an ALD apparatus according to a comparative example;

FIG. 11 is a diagram showing a modified example of the multilayer ALD apparatus shown in FIG. 9; and

FIG. 12 is a diagram showing a modified example of the multilayer ALD apparatus shown in FIG. 9.

### DETAILED DESCRIPTION

Hereinafter, an embodiment of the present disclosure will be described with reference to the drawings. It should be noted that the figure shows the X axis, Y axis, and Z axis orthogonal to each other as appropriate.

(Overall Structure of ALD Apparatus 1)

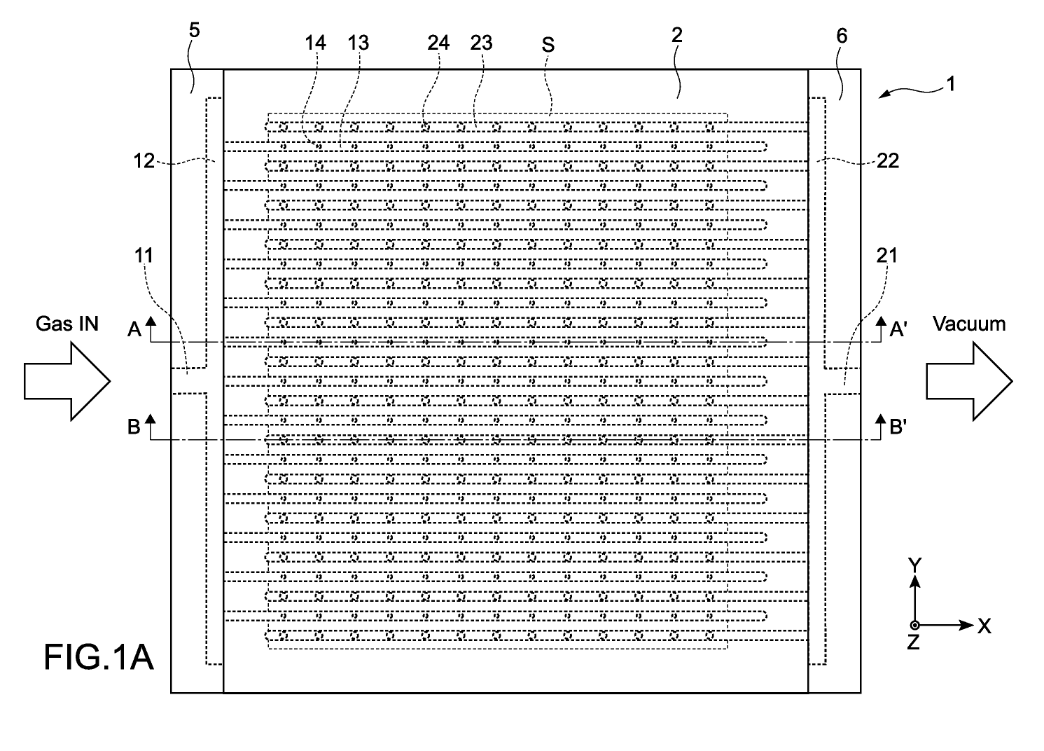

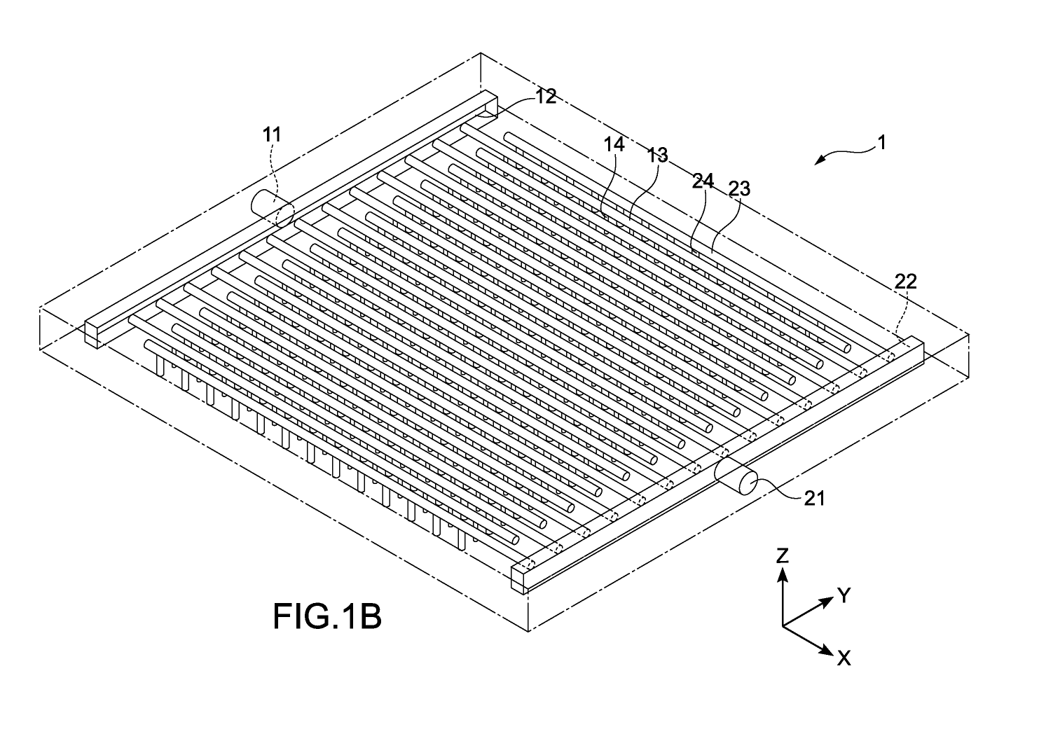

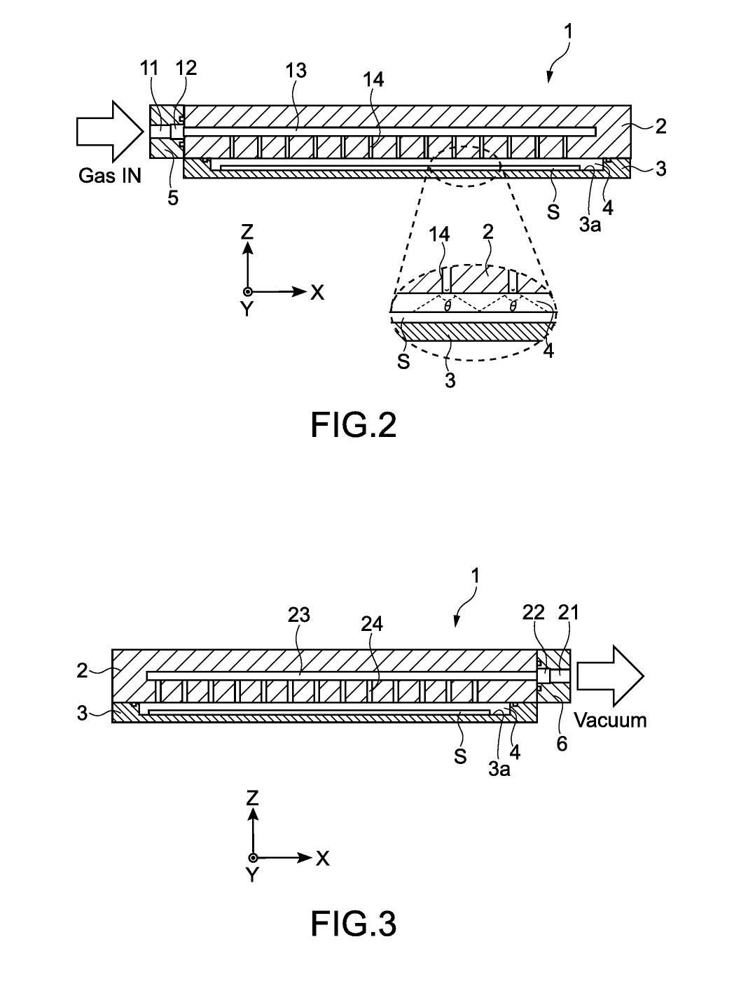

FIG. 1A is a plan view of an atomic layer deposition (ALD) apparatus 1 according to an embodiment of the present disclosure. FIG. 1B is a schematic diagram showing an internal structure of the ALD apparatus 1 shown in FIG. 1A. FIGS. 2 and 3 are cross-sectional diagrams of the ALD apparatus 1. FIG. 2 is a cross-sectional diagram taken along the line A-A′ of FIG. 1A, and FIG. 3 is a cross-sectional diagram taken along the line B-B′ of FIG. 1A. In FIG. 1A, an internal structure of the ALD apparatus 1 is seen through and indicated by broken lines. In FIG. 1B, the internal structure of the ALD apparatus 1 is shown schematically.

The ALD apparatus 1 includes a flow path formation member 2. The flow path formation member 2 is a rectangular plate extending in the X- and Y-axis directions. The flow path formation member 2 is a member in which a flow path for precursor gas is formed therein.

The flow path formation member 2 is formed of a solid-state material that is hardly damaged by the precursor gas and has sufficient heat resistance. Examples of such a material include a metal material and a ceramics material. A resin material can be adopted as the material for forming the flow path formation member 2 under the condition that the ALD apparatus 1 is used at a low temperature and gas is not generated by heating.

The material for forming the flow path formation member 2 can be determined based on a deposition substance and a flow path cleaning method. In this embodiment, a case where the deposition substance is alumina (Al₂O₃) will be described. Therefore, the flow path formation member 2 is formed of stainless steel that is hard to be damaged when an alumina film adhered onto a flow path is removed. However, when the deposition substance is not alumina, aluminum (Al) may be adopted as the material for forming the flow path formation member 2 for lightening the ALD apparatus 1, for example.

In the flow path formation member 2, supply paths 13 for supplying gas and exhaust paths 23 for exhaust, that extend in the X-axis direction, are arranged alternately at regular intervals in the Y-axis direction. The supply paths 13 extend from the left end portion of the flow path formation member 2 shown in FIGS. 1A to 3 to the right end portion thereof. The exhaust paths 23 extend from the right end portion of the flow path formation member 2 shown in FIGS. 1A to 3 to the left end portion thereof. The supply paths 13 do not penetrate the right end portion of the flow path formation member 2, and the exhaust paths 23 do not penetrate the left end portion of the flow path formation member 2.

Further, in the flow path formation member 2, supply ports 14 extending downwardly in the Z-axis direction from the supply paths 13 and exhaust ports 24 extending downwardly in the Z-axis direction from the exhaust paths 23 are provided. The supply ports 14 penetrate a lower surface of the flow path formation member 2 in the Z-axis direction from a plurality of positions provided at regular intervals in the X-axis direction on each of the supply paths 13. The exhaust ports 24 also penetrate the lower surface of the flow path formation member 2 in the Z-axis direction from a plurality of positions provided at regular intervals in the X-axis direction on each of the exhaust paths 23.

The supply ports 14 and the exhaust ports 24 are provided on the lower surface of the flow path formation member 2, but they only need to oppose a deposition surface of a substrate S. In other words, a surface on which the supply ports 14 are formed and a surface on which the exhaust ports 24 are formed may be provided stepwise in the Z-axis direction. For example, a lower end of the exhaust ports 24 in the Z-axis direction may be farther away from the deposition surface of the substrate S than a lower end of the supply ports 14 in the Z-axis direction.

The supply paths 13 each have a larger diameter than the supply ports 14 and each form a manifold together with the plurality of supply ports 14. The exhaust paths 23 each have a larger diameter than the exhaust ports 24 and each form a manifold together with the exhaust ports 24. The exhaust ports 24 each have a slightly larger diameter than the supply ports 14.

Since the supply path 13 and the plurality of supply ports 14 form a manifold, a gas pressure in the supply path 13 is maintained constant, and thus the plurality of supply ports 14 supply gas of a constant pressure to the deposition surface of the substrate S. Further, since the exhaust path 23 and the plurality of exhaust ports 24 form a manifold, a gas pressure in the exhaust path 23 is maintained constant, and thus the plurality of exhaust ports 24 exhaust gas at a constant pressure.

As shown in the partially-enlarged diagram of FIG. 2, the supply paths 13 supply gas to the deposition surface of the substrate S at a discharge angle θ. The discharge angle θ represents spreading of the gas discharged from the supply paths 13 and is determined based on the gas pressure and the like. The discharge angle θ can be adjusted based on the gas pressure and the like so that the gas discharged from the supply paths 13 is supplied to the entire deposition surface of the substrate S.

The supply paths 13, the exhaust paths 23, the supply ports 14, and the exhaust ports 24 are formed by subjecting the flow path formation member 2 to cutting processing using a drill. For forming the supply paths 13, the exhaust paths 23, the supply ports 14, and the exhaust ports 24, drill bits having diameters respectively corresponding to diameters of the paths and ports are used.

It should be noted that the ALD apparatus 1 of this embodiment is structured in correspondence with a deposition with respect to the substrate having a size of 300 mm×350 mm. Specifically, in the ALD apparatus 1, 13 supply paths 13 are provided, and 13 supply ports 14 are provided on each supply path 13. Also in the ALD apparatus 1, 13 exhaust paths 23 are provided, and 13 exhaust ports 24 are provided on each exhaust path 23. However, the numbers of supply paths 13, supply ports 14, exhaust paths 23, and exhaust ports 24 can be determined as appropriate.

The ALD apparatus 1 also includes connection members 5 and 6. The connection members 5 and 6 extend across the entire width of the flow path formation member 2 in the Y-axis direction and respectively attached at both end portions of the flow path formation member 2 in the X-axis direction. The connection member 5 is a member for connecting a gas supply source (not shown) and the supply paths 13. The connection member 6 is a member for connecting an exhaust mechanism (not shown) and the exhaust paths 23. The exhaust mechanism is structured as a pump in this embodiment but only needs to be capable of exhausting gas.

The connection member 5 is attached to the left end portion of the flow path formation member 2 in the X-axis direction where the supply paths 13 are opened. The connection member 6 is attached to the right end portion of the flow path formation member 2 in the X-axis direction where the exhaust paths 23 are opened. The connection members 5 and 6 are formed of stainless steel like the flow path formation member 2. However, the material for forming the connection members 5 and 6 can be changed as appropriate like the flow path formation member 2.

In the connection member 5, one supply chamber 12 that extends in the Y-axis direction and causes all the supply paths 13 to communicate and an introduction portion 11 for connecting the supply chamber 12 to the gas supply source are provided. The supply chamber 12 has a larger diameter than the supply paths 13 and forms a manifold with the supply paths 13.

In the connection member 6, one exhaust chamber 22 that extend in the Y-axis direction and causes all the exhaust paths 23 to communicate and an exhaust portion 21 for connecting the exhaust chamber 22 to a pump are provided. The exhaust chamber 22 has a larger diameter than the exhaust paths 23 and forms a manifold with the exhaust paths 23.

Since the supply chamber 12 and the plurality of supply paths 13 form a manifold, a gas pressure in the supply chamber 12 is maintained constant, and the gas pressure in the plurality of supply paths 13 is also maintained constant. Further, since the exhaust chamber 22 and the plurality of exhaust paths 23 form a manifold, a gas pressure in the exhaust chamber 22 is maintained constant, and thus the gas pressure in the plurality of exhaust paths 23 is also maintained constant.

The introduction portion 11 and the supply chamber 12 are formed by subjecting the connection member 5 to cutting processing using a drill, a milling cutter, or the like. Moreover, the exhaust portion 21 and the exhaust chamber 22 are formed by subjecting the connection member 6 to cutting processing using a drill, a milling cutter, or the like.

As described above, the introduction portion 11, the supply chamber 12, the supply paths 13, and the supply ports 14 are in communication with one another and constitute a supply mechanism to be connected to the gas supply source. The supply mechanism includes a manifold constituted of the supply chamber 12 and the supply paths 13 and a manifold constituted of the supply path 13 and the supply ports 14. In other words, the supply mechanism has a structure in which the manifolds are combined in two steps.

Further, the exhaust portion 21, the exhaust chamber 22, the exhaust paths 23, and the exhaust ports 24 are in communication with one another and constitute an exhaust mechanism to be connected to the pump. The exhaust mechanism includes a manifold constituted of the exhaust chamber 22 and the exhaust paths 23 and a manifold constituted of the exhaust path 23 and the exhaust ports 24. In other words, the exhaust mechanism has a structure in which the manifolds are combined in two steps.

The ALD apparatus 1 also includes a holding member 3. The holding member 3 extends across the entire width of the flow path formation member 2 in the X- and Y-axis directions. A circumferential edge portion of the holding member 3 is coupled to the flow path formation member 2 across the entire circumference so as to cover the lower surface of the flow path formation member 2 in the Z-axis direction. The holding member 3 is a member for forming a deposition chamber 4 between the holding member 3 and the flow path formation member 2. The holding member 3 is formed of stainless steel like the flow path formation member 2. However, the material for forming the holding member 3 can be changed as appropriate like the flow path formation member 2.

The holding member 3 is surrounded by the circumferential edge portion to be coupled to the flow path formation member 2 and includes a stage 3a as a surface opposing the supply ports 14 and the exhaust ports 24. By cutting the upper surface of the holding member 3 in the Z-axis direction, the stage 3a becomes parallel to the lower surface of the flow path formation member 2 in the Z-axis direction. In other words, the stage 3a is at a position concaved downwardly in the Z-axis direction from the upper surface of the holding member 3 in the Z-axis direction at the circumferential edge portion thereof.

The holding member 3 forms the deposition chamber 4 between the stage 3a and the lower surface of the flow path formation member 2 in the Z-axis direction. The deposition chamber 4 is a space closed by the flow path formation member 2 and the holding member 3 except for the supply ports 14 and the exhaust ports 24. The stage 3a is structured as a holding portion that holds the substrate S.

The substrate S is set such that a surface thereof on the other side of the deposition surface opposes the stage 3a and the deposition surface opposes the flow path formation member 2. Therefore, the deposition surface of the substrate S set on the stage 3a is exposed on the supply ports 14 and exhaust ports 24 side of the flow path formation member 2.

The setting of the substrate S on the stage 3a in the deposition chamber 4 may be carried out manually or automatically by a robot or the like. Moreover, the ALD apparatus 1 may have a structure in which a whole cassette accommodating the substrate S can be set in the deposition chamber 4.

As shown in FIG. 1A, the positions of the supply ports 14 and exhaust ports 24 of the ALD apparatus 1 are allocated evenly across the entire deposition surface of the substrate S set on the stage 3a. As a result, the ALD apparatus 1 can form a thin film under the same condition across the entire deposition surface of the substrate S.

Although the substrate S of this embodiment is a glass substrate, the type of substrate is not limited. Examples of the substrate on which a thin film can be formed in the ALD apparatus 1 include various ceramics substrate, a silicon substrate, a resin substrate, and an organic film substrate. The ALD apparatus 1 can also form a thin film on a metal substrate formed of aluminum, copper, and the like or a complex substrate constituted by combining a plurality of types of materials.

(Deposition Method for ALD Apparatus 1)

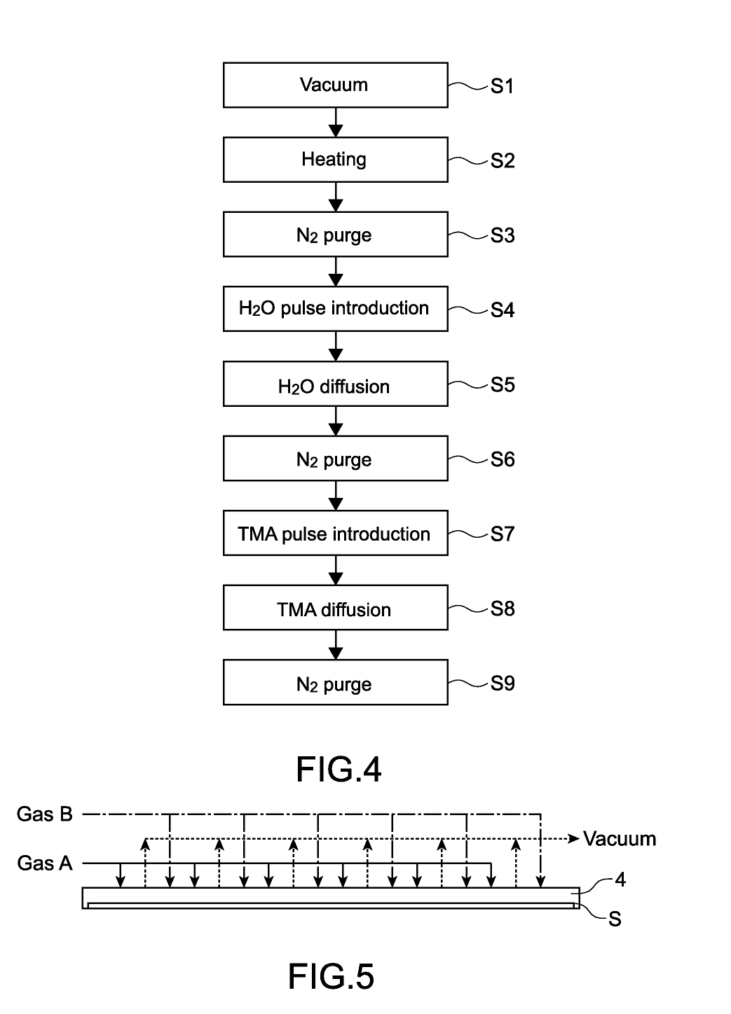

FIG. 4 is a flowchart showing a deposition method for the ALD apparatus 1. The deposition method of this embodiment will be described with reference to FIGS. 1A to 3 along the flowchart shown in FIG. 4. Specifically, Steps S1 to S9 shown in FIG. 4 are carried out while the substrate S is set on the stage 3a.

In Step S1, vacuuming of the deposition chamber 4 is performed the pump connected to the exhaust portion 21. At this time, a valve (not shown) provided on the introduction portion 11 side is closed, and thus the ALD apparatus 1 is in a sealed state. As a result, the entire space in the ALD apparatus 1 including the deposition chamber 4 is in vacuum. It is desirable for the vacuum degree of the deposition chamber 4 to be high in Step S1.

Specifically, air inside the ALD apparatus 1 is exhausted outside the ALD apparatus 1 via the exhaust mechanism of the exhaust ports 24, the exhaust paths 23, the exhaust chamber 22, and the exhaust portion 21. Furthermore, although details will be given later, the pump is also connected to the introduction portion 11 so that air inside the ALD apparatus 1 is exhausted outside the ALD apparatus 1 also by the supply mechanism constituted of the supply ports 14, the supply paths 13, the supply chamber 12, and the introduction portion 11.

With this structure, the exhaust time inside the ALD apparatus 1 is shortened. Accordingly, Step S1 is shortened, and the exhaustion in the subsequent steps can also be shortened.

In Step S2, the entire ALD apparatus 1 is heated. The heating temperature of the ALD apparatus 1 is set based on a reaction temperature of the precursor gas, a heat resistance temperature of the deposition surface of the substrate S, and the like. In this embodiment, trimethylaluminum (TMA) and H₂O (water vapor) are used as the precursor gas, and the heating temperature of the ALD apparatus 1 is set to be 50° C. or more and 320° C. or less. It should be noted that when the precursor gas differ, the heating temperature can be changed as appropriate.

In Step S3, N₂ purge of the deposition chamber 4 is performed. In Step S3, N₂ as inert gas is introduced into the deposition chamber 4 vacuumed in Step S1, and the deposition chamber 4 is vacuumed again. Accordingly, gas that has remained inside the deposition chamber 4 after Step S1 is replaced by N₂ and exhausted outside the deposition chamber 4. By Step S3, an influence of gas that has remained after Step S1 can be removed.

Specifically, N₂ is introduced into the deposition chamber 4 via the supply mechanism constituted of the introduction portion 11, the supply chamber 12, the supply paths 13, and the supply ports 14. Moreover, N₂ in the deposition chamber 4 is exhausted outside the ALD apparatus 1 by the exhaust mechanism (24, 23, 22, 21) and the supply mechanism (14, 13, 12, 11).

In Step S4, H₂O is pulse-introduced into the deposition chamber 4. Specifically, by introducing H₂O from the introduction portion 11 for a predetermined time, H₂O is discharged toward the deposition surface of the substrate S from the supply ports 14. At this time, the valve (not shown) provided on the exhaust portion 21 side is closed, and the deposition chamber 4 is not exhausted. The time and number of times H₂O is pulse-introduced can be determined based on an area of the deposition surface of the substrate S. Moreover, the introduction amount of N₂ can be determined under the condition with which the flow rate of N₂ becomes 30 to 200 sccm and the pressure inside the deposition chamber 4 becomes about 4*10-1 torr (5.33*10 Pa).

H₂O is introduced into the deposition chamber 4 via the supply mechanism (14, 13, 12, 11). More specifically, H₂O introduced into the introduction portion 11 is diffused inside the supply chamber 12 so that the supply chamber 12 becomes a constant pressure. Then, H₂O is introduced into the supply paths 13 from the supply chamber 12 at a constant pressure and diffused inside the supply paths 13 so as to become a constant pressure. Then, H₂O is introduced into the supply ports 14 from the supply paths 13 at a constant pressure. Therefore, H₂O is discharged from all the supply ports 14 at a constant pressure.

As described above, in this embodiment, H₂O is supplied to the deposition surface of the substrate S from all the supply ports 14 at a constant discharge pressure. Therefore, a concentration distribution of H₂O is hard to be caused on the deposition surface of the substrate S.

In Step S5, H₂O introduced into the deposition chamber 4 is diffused inside the entire deposition chamber 4. Specifically, the valve provided on the introduction portion 11 side is closed after Step S4, and such a state is maintained. As a result, the concentration of H₂O in the deposition chamber 4 becomes uniform. In other words, by Step S5, the H₂O supply condition becomes constant across the entire deposition surface of the substrate S.

In this embodiment, since the H₂O concentration distribution is hard to be caused on the deposition surface of the substrate S in Step S4, the time for Step S5 is remarkably shortened. Further, it is also possible to omit Step S5 when the H₂O concentration is sufficiently uniform in Step S4 based on the uniformity required for a thin film to be formed on the deposition surface of the substrate S.

In Step S6, N₂ purge of the deposition chamber 4 is performed. In Step S6, the deposition chamber 4 is vacuumed, N₂ as inert gas is introduced into the deposition chamber 4, and the deposition chamber 4 is vacuumed again. As a result, H₂O is discharged from the deposition chamber 4.

In Step S7, TMA is pulse-introduced into the deposition chamber 4. Specifically, by introducing TMA from the introduction portion 11 for a predetermined time, TMA is discharged to the deposition surface of the substrate S from the supply ports 14. At this time, the valve (not shown) provided on the exhaust portion 21 side is closed, and exhaustion of the deposition chamber 4 is not performed. The time and number of times TMA is pulse-introduced can be determined based on an area of the deposition surface of the substrate S. Moreover, the introduction amount of N₂ can be determined under the condition with which the flow rate of N₂ becomes 30 to 200 sccm and the pressure inside the deposition chamber 4 becomes about 4*10-1 torr (5.33*10 Pa). The flow rate of N₂ can also be determined based on the TMA pulse introduction time or the volume of the deposition chamber 4, for example.

TMA is introduced into the deposition chamber 4 via the supply mechanism (11, 12, 13, 14). More specifically, TMA introduced into the introduction portion 11 is diffused inside the supply chamber 12 so as to become a constant pressure in the supply chamber 12. Then, TMA is introduced into the supply paths 13 from the supply chamber 12 at a constant pressure and diffused inside the supply paths 13 so as to become a constant pressure in the supply paths 13. Then, TMA is introduced into the supply ports 14 from the supply paths 13. Therefore, TMA is discharged at a constant pressure from all the supply ports 14.

As described above, in this embodiment, TMA is supplied to the deposition surface of the substrate S at a constant discharge pressure from all the supply ports 14. As a result, the TMA concentration distribution is hard to be caused on the deposition surface of the substrate S.

In Step S8, TMA introduced into the deposition chamber 4 is diffused inside the entire deposition chamber 4. Specifically, the valve provided on the introduction portion 11 side is closed after Step S7, and such a state is maintained. As a result, the concentration of TMA in the deposition chamber 4 becomes uniform. In other words, by Step S8, the TMA supply condition becomes constant across the entire deposition surface of the substrate S.

In this embodiment, since the TMA concentration distribution is hard to be caused on the deposition surface of the substrate S in Step S7, the time for Step S8 is remarkably shortened. Further, it is also possible to omit Step S8 when the TMA concentration is sufficiently uniform in Step S7 based on the uniformity required for a thin film to be formed on the deposition surface of the substrate S.

In Step S9, N₂ purge of the deposition chamber 4 is performed. In Step S9, the deposition chamber 4 is vacuumed, N₂ as inert gas is introduced into the deposition chamber 4, and the deposition chamber 4 is vacuumed again. As a result, TMA is discharged from the deposition chamber 4.

With Steps S4 to S9 being one cycle, the ALD apparatus 1 is structured so that a layer corresponding to one molecular layer of alumina in the vicinity of a stoichiometry composition (Al₂O₃) is formed on the deposition surface of the substrate S. Therefore, by performing Step S4 to S9 again after Step S9, a layer of alumina corresponding to two particles is formed on the deposition surface of the substrate S. In the deposition method that uses the ALD apparatus 1, Step S4 to S9 are repeated according to the thickness of the thin film to be formed on the deposition surface of the substrate S. As described above, since the ALD apparatus 1 can control the film thickness of the thin film in a molecule unit, controllability regarding the film thickness of the thin film is excellent.

Moreover, in the ALD apparatus 1, the deposition chamber 4 is set to an air pressure after Step S4 to S9 are repeated a predetermined number of times, and the substrate S is taken out.

The ALD apparatus 1 is suitable for forming an inter-layer insulation film of a TFT (Thin Film Transistor) for a liquid crystal display panel and an organic EL (Electro Luminescence) panel, or an organic EL water vapor barrier film. In the ALD apparatus 1, an alumina thin film in which a film thickness error range is within 3%, a density is 2.9 g/cm³ or more, and a refractive index is 1.6 or more was formed on a 300 mm×350 mm substrate, for example. In the alumina thin film, a sufficient insulation property and water vapor barrier property were obtained.

It should be noted that in the ALD apparatus 1 of this embodiment, one supply mechanism (11, 12, 13, 14) has been used with respect to the two types of precursor gas. However, it is favorable to change the supply mechanism based on the type of precursor gas. This is because, when two types of precursor gas alternately pass one supply mechanism, the precursor gas slightly remaining in the supply mechanism may cause crosstalk.

When crosstalk is caused by the precursor gas in the supply mechanism, the precursor gas may show a gas phase reaction or may be precipitated inside the supply mechanism. When the precursor gas shows a gas phase reaction, the precursor gas that has shown the gas phase reaction is wasted. Moreover, when the precursor gas is precipitated in the supply mechanism, the volume of the supply mechanism may change, and the supply ports 14 may be blocked by the precipitate.

FIG. 5 is an explanatory diagram schematically showing the supply mechanism and exhaust mechanism according to a modified example of the ALD apparatus 1. This ALD apparatus includes a first supply mechanism that supplies first precursor gas A (indicated by solid line) and a second supply mechanism that supplies second precursor gas B (indicated by dashed line). It should be noted that also in this ALD apparatus, one exhaust mechanism (indicated by broken line) is provided. In the ALD apparatus, the supply mechanisms are provided respectively for the gas A and gas B. Therefore, crosstalk is not caused between the gas A and gas B in the supply mechanisms.

(Size of Respective Portions of ALD Apparatus 1)

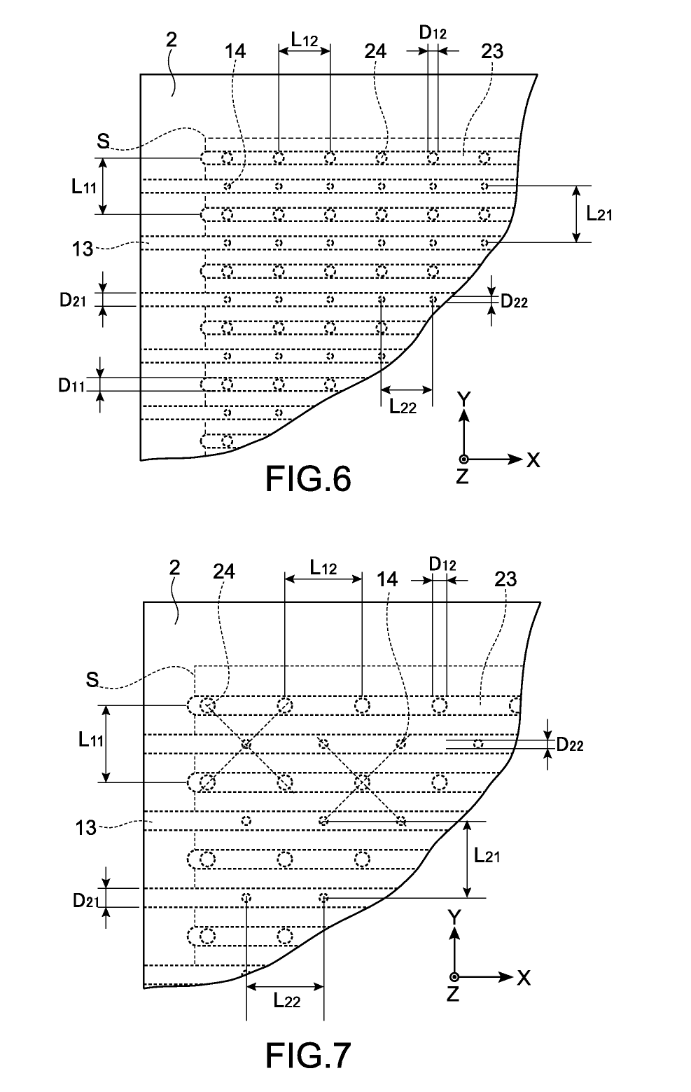

FIG. 6 is a plan view exemplifying a size of the supply mechanism and exhaust mechanism of the ALD apparatus 1. This example is designed presupposing that a pump having exhaust performance of 100 to 1000 l/min is used. An interval L₁₁ of the supply ports 14 in the Y-axis direction and an interval L₂₁ of the exhaust ports 24 in the Y-axis direction are both 22 mm. An interval L₁₂ of the supply ports 14 in the X-axis direction and an interval L₂₂ of the exhaust ports 24 in the X-axis direction are both 20 mm. A diameter D₁₁ of the supply paths 13 and a diameter D₂₁ of the exhaust paths 23 are both 5 mm. A diameter D₁₂ of the supply ports 14 is 2 mm, and a diameter D₂₂ of the exhaust ports 24 is 4 mm.

Further, a distance between the supply ports 14 and the deposition surface of the substrate S is equal to or smaller than the intervals L₁₁ and L₁₂ of the supply ports 14. As the distance between the supply ports 14 and the deposition surface of the substrate S becomes smaller, the volume of the deposition chamber 4 decreases. Therefore, it is possible to shorten the time for exhausting the deposition chamber 4. In the ALD apparatus 1, the distance between the supply ports 14 and the deposition surface of the substrate S is 7 mm and has successfully been reduced to as small as 1 mm.

On the other hand, assuming that the gas discharge angle θ (see FIG. 3) at the supply ports 14 is constant, the intervals L₁₁ and L₁₂ of the supply ports 14 need to be made shorter as the distance between the supply ports 14 and the deposition surface of the substrate S becomes smaller for supplying gas to the entire deposition surface of the substrate S. For shortening the intervals L₁₁ and L₁₂ of the supply ports 14, costs for processing the flow path formation member 2 become high. It is realistic to set the distance between the supply ports 14 and the deposition surface of the substrate S to be about 2 mm.

Furthermore, it is favorable for the intervals L₁₁ and L₁₂ of the supply ports 14 to be small, but when the intervals L₁₁ and L₁₂ of the supply ports 14 are made small, the diameter D₁₁ of the supply ports 14 needs to be increased. Therefore, it is favorable to determine the values of L₁₁, L₁₂, and D₁₁ while comprehensively considering the influences thereof.

The diameter D₂₂ of the exhaust ports 24 is larger the better although it is limited by the diameter D₂₁ of the exhaust paths 23 and the intervals L₂₁ and L₂₂ of the exhaust ports 24. This is because the conductance during exhaustion of the deposition chamber 4 can be increased, and the deposition chamber 4 can be uniformly exhausted.

FIG. 7 is a plan view exemplifying a size of the supply mechanism and exhaust mechanism according to a modified example of the ALD apparatus 1. The supply mechanism and the exhaust mechanism are designed for achieving cost cut. Specifically, by improving efficiency of gas supply and exhaustion, this example is designed presupposing that a pump having exhaustion performance of 100 to 1000 l/min is used.

As shown in FIG. 7, the intervals of the supply ports 14 and the exhaust ports 24 are wide, the exhaust ports 24 are arranged diagonally from the 4 adjacent supply ports 14, and the supply ports 14 are arranged diagonally from the 4 adjacent exhaust ports 24. The interval L₁₁ of the supply ports 14 in the Y-axis direction and the interval L₂₁ of the exhaust ports 24 in the Y-axis direction are both 30 mm. The interval L₁₂ of the supply ports 14 in the X-axis direction and the interval L₂₂ of the exhaust ports 24 in the X-axis direction are both 30 mm. The diameter D₁₁ of the supply paths 13 and the diameter D₂₁ of the exhaust paths 23 are both 8 mm. The diameter D₁₂ of the supply ports 14 is 3 mm, and the diameter D₂₂ of the exhaust ports 24 is 6 mm.

(Multilayer ALD Apparatus 100)

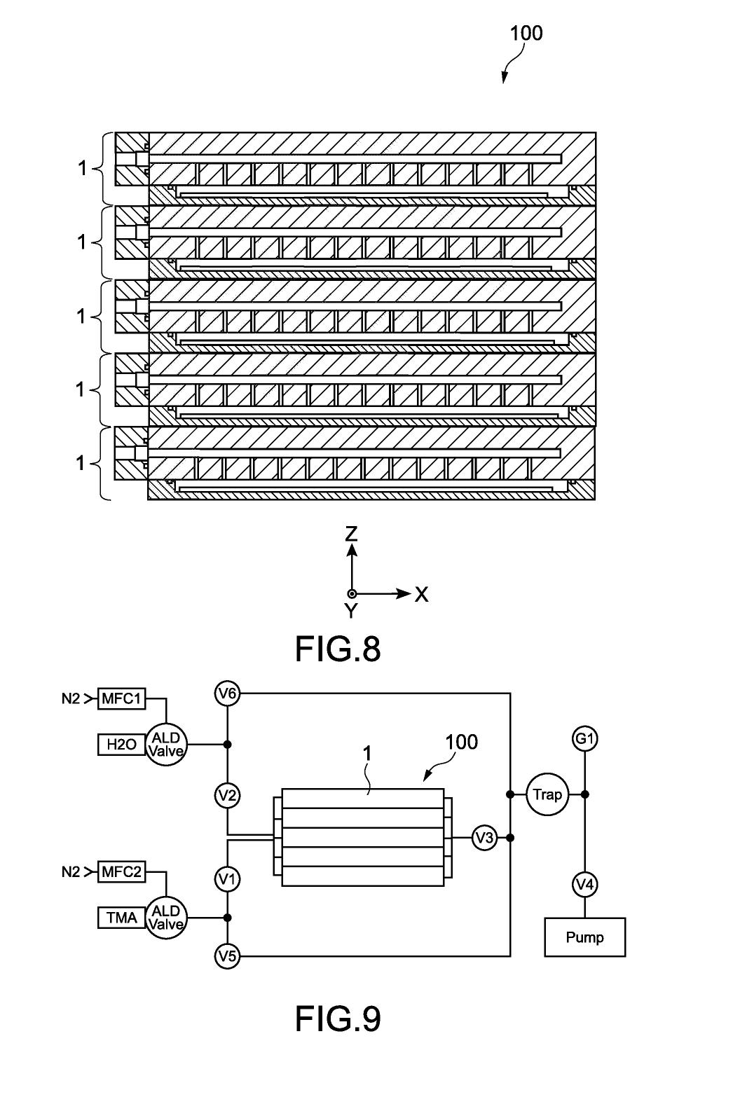

FIG. 8 is a cross-sectional diagram of a multilayer ALD apparatus 100 according to this embodiment. In the multilayer ALD apparatus 100, with the ALD apparatus 1 being one unit, 5 units are laminated in the Z-axis direction. Since the ALD unit 1 has the same structure as the ALD apparatus 1 described above, descriptions thereof will be omitted. A gas supply source is connected in parallel to the introduction portion 11 of each ALD unit, and a pump is connected in parallel to the exhaust portion 21. Accordingly, in the multilayer ALD apparatus 100, thin films can be simultaneously deposited on the deposition surfaces of 5 substrates S.

It should be noted that in the ALD apparatus having a structure aiming at mass production, a deposition condition generally varies depending on the number of substrates to be set. However, in the multilayer ALD apparatus 100, the substrate S does not need to be set in all ALD units 1. Also when the substrate S is set in only one ALD unit 1, for example, the multilayer ALD apparatus 100 is capable of forming a thin film under the same condition as in the case of setting the substrate S in all the ALD units 1.

Further, in the multilayer ALD apparatus 100, the number of ALD units to be laminated can be changed as appropriate. For example, the multilayer ALD apparatus may have a structure in which 10 ALD units are laminated. In this case, the multilayer ALD apparatus can simultaneously form thin films on the deposition surfaces of 10 substrates S at maximum.

(Gas Supply System and Exhaust System of Multilayer ALD Apparatus 100)

FIG. 9 is a schematic diagram showing a gas supply system and an exhaust system of the multilayer ALD apparatus 100. It should be noted that although descriptions will be given on the multilayer ALD apparatus 100 herein, since the number of ALD units of the multilayer ALD apparatus 100 is 1 regarding the ALD apparatus 1 described above, the same descriptions can be applied.

An H₂O supply source as a first gas supply source is connected to each introduction portion 11 of the multilayer ALD apparatus 100 via an ALD valve and a valve V2. Connected to an H₂O ALD valve via a mass flow controller (MFC) is an N₂ supply source. With this structure, H₂O can be supplied to the introduction portion 11 of the multilayer ALD apparatus 100 while a flow rate thereof is precisely controlled by the ALD valve.

A TMA supply source as a second gas supply source is connected to each introduction portion 11 of the multilayer ALD apparatus 100 via the ALD valve and a valve V1. Connected to TMA ALD valve via a mass flow controller (MFC) is the N₂ supply source. With this structure, TMA can be supplied to the introduction portion 11 of the multilayer ALD apparatus 100 while a flow rate thereof is precisely controlled by the ALD valve.

A generally-used vacuum pump is used as the pump. A type of the vacuum pump or a combination thereof can be determined as appropriate. In this embodiment, the vacuum pump is structured as a dry pump. The dry pump may be used independently or in a multistage. When the dry pump is used in a multistage, a mechanical booster pump (MBP) and a turbo-molecular pump can be exemplified as a main pump, and a root pump, a scroll pump, and a screw pump can be exemplified as an auxiliary pump that aids the main pump. It should be noted that a vacuum pump can be adopted instead of the dry pump, and a rotary pump can be exemplified as such a vacuum pump.

Moreover, the pump is connected to the introduction portion 11 of the multilayer ALD apparatus 100 via a valve V4, a trap, a valve V6, and the valve V2. The pump is also connected to the introduction portion 11 of the multilayer ALD apparatus 100 via the valve V4, the trap, a valve V5, and the valve V1. A vacuum gauge for monitoring a pressure in the multilayer ALD apparatus 100 may be provided in the exhaust system.

The valve V4, the trap, the valve V6, and the valve V2 constitute a first bypass path for connecting the pump and the introduction portion 11, and the valve V4, the trap, the valve V5, and the valve V1 constitute a second bypass path for connecting the pump and the introduction portion 11. With this structure, in the multilayer ALD apparatus 100, the supply mechanism and the exhaust mechanism can be exhausted via not only the exhaust portion 21 but also the introduction portion 11. Accordingly, the exhaustion time in the multilayer ALD apparatus 100 can be shortened.

Specifically, a thin film having a film thickness of 50 nm was formed on the deposition surfaces of 10 substrates S at a processing temperature of 120° C. As the ALD apparatus of this embodiment, a multilayer ALD apparatus in which 10 ALD units 1 are laminated was used. While the processing time for obtaining a favorable insulation property was 15.5 hours in a general multilayer ALD apparatus, the processing time for obtaining a favorable insulation property was 1.4 hour in the multilayer ALD apparatus of this embodiment. As described above, in the multilayer ALD apparatus of this embodiment, by shortening the exhaustion time, it was possible to remarkably shorten the processing time. In addition, in the multilayer ALD apparatus of this embodiment, uniformity of the film thickness of the thin films formed on the deposition surfaces of the substrates S was improved. The uniformity of the film thickness of the thin films was evaluated based on an index indicating within how much % an error with respect to a target film thickness (50 nm in this embodiment) falls with respect to the target film thickness. Specifically, while the uniformity was about 3% in the general ALD apparatus, it was improved to about 1% in the multilayer ALD apparatus 100 of this embodiment.

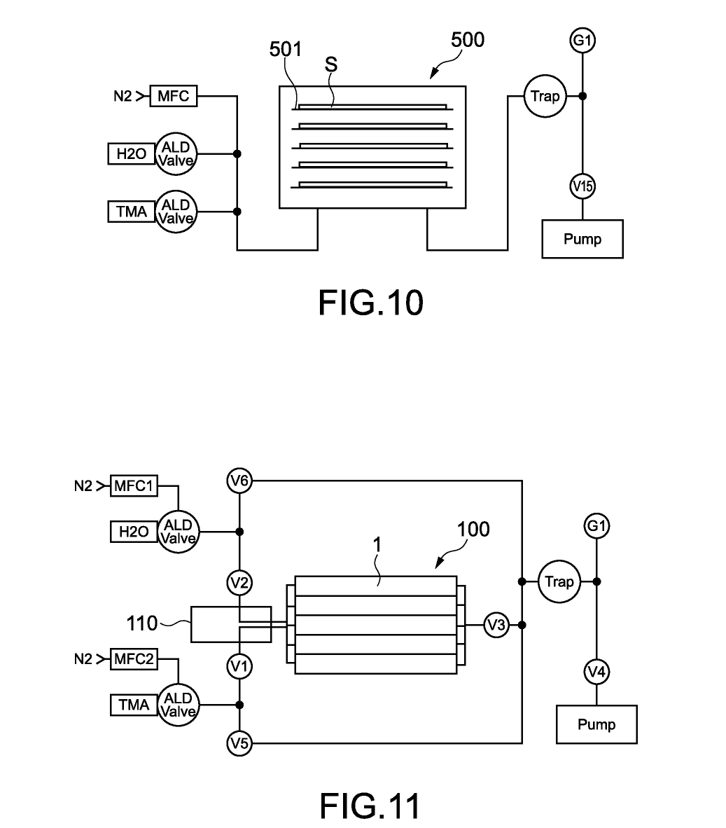

FIG. 10 is a schematic diagram showing a gas supply system and an exhaust system of a multilayer ALD apparatus 500 according to a comparative example of this embodiment. The multilayer ALD apparatus 500 has a structure in which shelves 501 in a plurality of steps are arranged in a vacuum chamber. In the multilayer ALD apparatus 500, the gas supply and exhaustion are each performed from a corresponding position.

In other words, by the precursor gas being diffused in the multilayer ALD apparatus 500, the precursor gas is supplied to the deposition surfaces of the substrates S set on the shelves 501. Further, in the multilayer ALD apparatus 500, the precursor gas is discharged after being diffused for a predetermined time. By repeating the gas supply and exhaustion in the multilayer ALD apparatus 500, a thin film can be formed on the deposition surfaces of the substrates S set on the shelves 501.

In the multilayer ALD apparatus 500, the H₂O supply source as the first gas supply source and the TMA supply source as the second gas supply source are connected to the multilayer ALD apparatus 500 via the ALD valves. The N₂ supply source is also connected to the multilayer ALD apparatus 500 via the MFC. With this structure, H₂O, TMA, and N₂ can be supplied to the multilayer ALD apparatus 500 while flow rates thereof are precisely controlled by the ALD valves.

The pump is connected to the multilayer ALD apparatus 500 via a valve V15 and a trap. Accordingly, in the multilayer ALD apparatus 500, exhaustion can be performed using the pump.

It should be noted that since the gas supply is performed from one position in the multilayer ALD apparatus 500 of the comparative example, a concentration distribution of the precursor gas may be caused, and thus the precursor gas may not be supplied uniformly to the deposition surfaces of the substrates S. Moreover, in the multilayer ALD apparatus 500, exhaustion from one position may also cause a concentration distribution of the precursor gas. On the other hand, in the multilayer ALD apparatus 100 of this embodiment, since the deposition chamber is provided for each substrate S and the precursor gas is supplied from the supply ports opposing the deposition surface of each substrate S, the precursor gas is uniformly supplied to all deposition surfaces of the substrates S.

Furthermore, the volume of the multilayer ALD apparatus 500 of the comparative example is larger than that of the multilayer ALD apparatus 100 of this embodiment. Therefore, in the multilayer ALD apparatus 100 of this embodiment, the exhaust time can be made shorter than that of the multilayer ALD apparatus 500 of the comparative example.

Moreover, since the multilayer ALD apparatus 500 does not include a flow path, a conductance during exhaustion is large. On the other hand, since the multilayer ALD apparatus 100 of this embodiment includes a flow path, the conductance during exhaustion is smaller than that of the multilayer ALD apparatus 500. However, since the exhaustion of the supply mechanism and the exhaust mechanism is performed not only via the exhaust portion 21 but also via the introduction portion 11 as described above, the conductance during exhaustion is sufficiently increased. Therefore, exhaustion in a short time is possible in the multilayer ALD apparatus 100.

### Modified Example

FIG. 11 is a schematic diagram of a multilayer ALD apparatus according to a modified example of the multilayer ALD apparatus 100 of this embodiment. The multilayer ALD apparatus adopts a so-called remote plasma system and has a structure in which a high-frequency plasma unit 110 is added to the multilayer ALD apparatus 100. The high-frequency plasma unit 110 is provided adjacent to the introduction portion 11 of the multilayer ALD apparatus 100, and a high-frequency voltage is applied to H₂O and TMA before being introduced into the introduction portion 11 to cause plasma, with the result that H₂O and TMA are activated by plasma. In the multilayer ALD apparatus, H₂O and TMA activated by plasma are supplied to the deposition surfaces of the substrates S, and thus reactions of H₂O and TMA are activated.

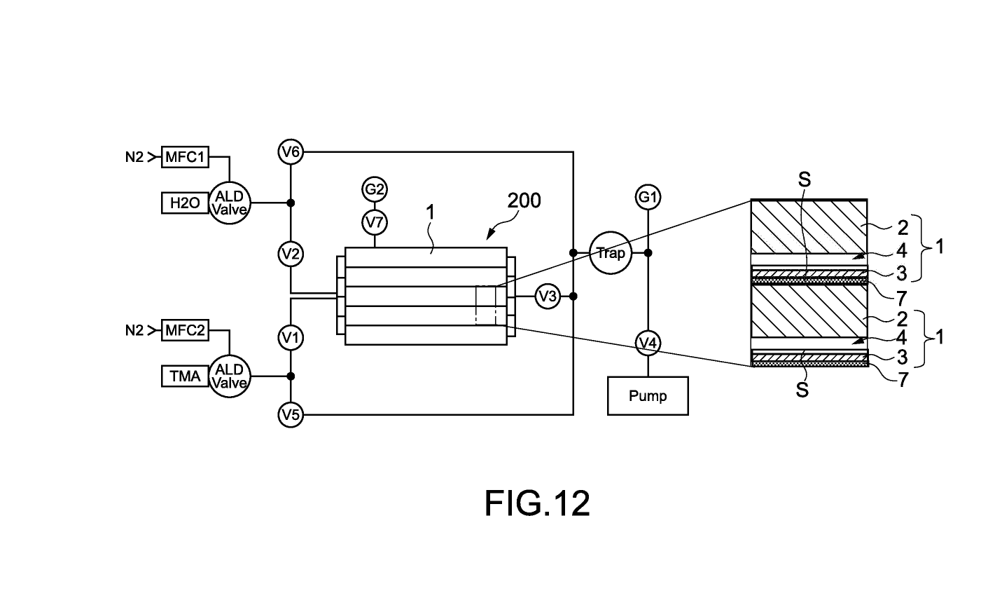

FIG. 12 is a schematic diagram of a multilayer ALD apparatus 200 according to a modified example of the multilayer ALD apparatus 100 of this embodiment. The multilayer ALD apparatus 200 adopts a so-called direct plasma system and has a structure capable of causing plasma of precursor gas in the deposition chamber 4. In each ALD unit 1, the flow path formation member 2 functions as an anode (first electrode), and the holding member 3 functions as a cathode (second electrode). The flow path formation member 2 and the holding member 3 are connected to a power supply (not shown). The multilayer ALD apparatus 200 includes an insulation layer 7 between the ALD units 1. Of the ALD units 1 adjacent in the Z-axis direction, the insulation layer 7 insulates the holding member 3 of the upper-side ALD unit 1 and the flow path formation member 2 of the lower-side ALD unit 1. In the multilayer ALD apparatus 200, a high-frequency voltage is applied between the flow path formation member 2 and the holding member 3 of the ALD units 1 to cause plasma in the deposition chamber 4.

Heretofore, the embodiment of the present disclosure has been described. However, the present disclosure is not limited to the embodiment above and can be variously modified without departing from the gist of the present disclosure.

For example, in the embodiment above, alumina has been formed on the deposition surface of the substrate S by the ALD apparatus. However, in the ALD apparatus of this embodiment, various types of thin films can be formed. Examples of such thin films include various oxide films, various nitride films, various metal films, various sulfide films, and various fluoride films.

Examples of the oxide film include TiO₂, TaO₅, Nb₂O₅, ZrO₂, HfO₂, SnO₂, ZnO, SiO₂, and InO₃. Examples of the nitride film include AlN, TaNx, TiN, MoN, ZrN, HfN, and GaN. Examples of the metal film include Pt, Pd, Cu, Fe, Co, and Ni. Examples of the sulfide film include ZnS, SrS, CaS, and PbS. Examples of the fluoride film include CaF₂, SrF₂, and ZnF₂.

Further, the shape of the supply ports and exhaust ports on the XY plane is not limited to a circle. The shape of the supply ports and exhaust ports may be an oval or a polygon, for example. Alternatively, the supply ports and exhaust ports may be slits. In this case, the shape of the slits may be a straight line or an arc, or may be bent complicatedly.

Furthermore, in the ALD apparatus, the supply ports and exhaust ports only need to oppose the deposition surface of the substrate S, and the ALD apparatus does not need to have the supply mechanism and the exhaust mechanism of this embodiment. The supply ports and exhaust ports may be structured as a so-called showerhead. In this case, the showerhead opposes the deposition surface of the substrate S, and openings of the showerhead are each structured as either the supply port or the exhaust port.

It should be noted that the present disclosure may also take the following structures.

(1) An atomic layer deposition apparatus, including:

a sealable deposition chamber;

a holding portion configured to hold a substrate including a deposition surface in the deposition chamber;

a supply mechanism that includes an introduction portion connected to a gas supply source that supplies gas and is configured to supply gas introduced into the introduction portion to the deposition chamber from a position opposing the deposition surface; and

an exhaust mechanism that includes an exhaust portion connected to an exhaust mechanism capable of exhausting gas and is configured to exhaust the deposition chamber from a position opposing the deposition surface.

(2) The atomic layer deposition apparatus according to (1) above,

in which the supply mechanism further includes a supply port that is connected to the introduction portion and opposes the deposition surface, and

in which the exhaust mechanism further includes an exhaust port that is connected to the exhaust portion and opposes the deposition surface.

(3) The atomic layer deposition apparatus according to (2) above,

in which the supply port and the exhaust port are adjacent to each other.

(4) The atomic layer deposition apparatus according to (2) or (3) above,

in which the supply mechanism further includes a plurality of supply ports and a supply path that connects the plurality of supply ports to the introduction portion and forms a manifold with the plurality of supply ports, and

in which the exhaust mechanism further includes a plurality of exhaust ports and an exhaust path that connects the plurality of exhaust ports to the exhaust portion and forms a manifold with the plurality of exhaust ports.

(5) The atomic layer deposition apparatus according to (4) above,

in which the supply path, the supply ports, the exhaust path, and the exhaust ports are all formed on a single flow path formation member.

(6) The atomic layer deposition apparatus according to (4) or (5) above, further including

a plurality of supply mechanisms,

in which the plurality of supply mechanisms supply different types of gas to the deposition chamber.

(7) The atomic layer deposition apparatus according to any one of (4) to (6) above,

in which the supply mechanism further includes a plurality of supply paths and an introduction chamber that connects the plurality of supply paths to the introduction portion and forms a manifold with the plurality of supply paths, and

in which the exhaust mechanism further includes a plurality of exhaust paths and an exhaust chamber that connects the plurality of exhaust paths to the exhaust portion and forms a manifold with the plurality of exhaust paths.

(8) The atomic layer deposition apparatus according to (7) above,

in which the plurality of supply paths and the plurality of exhaust paths are arranged alternately.

(9) The atomic layer deposition apparatus according to any one of (1) to (8) above, further including

a bypass path that connects the exhaust mechanism and the introduction portion.

(10) The atomic layer deposition apparatus according to any one of (1) to (9) above, further including

a plasma unit that is provided between the gas supply source and the introduction portion and causes plasma of the gas to be introduced into the introduction portion.

(11) The atomic layer deposition apparatus according to any one of (1) to (10) above, further including

a pair of electrodes that are provided inside the deposition chamber and connected to a power supply to cause plasma of the gas in the deposition chamber.

(12) The atomic layer deposition apparatus according to (11) above,

in which the exhaust mechanism and the supply mechanism are both formed on a single flow path formation member, and

in which the holding portion and the flow path formation member constitute the pair of electrodes.

(13) The atomic layer deposition apparatus according to any one of (1) to (12) above, further including

a plurality of atomic layer deposition units each including the deposition chamber, the holding portion, the supply mechanism, and the exhaust mechanism.

(14) The atomic layer deposition apparatus according to (13) above,

in which the plurality of atomic layer deposition units are laminated in a direction vertical to the deposition surface.

(15) An atomic layer deposition method, including:

supplying gas from a first position opposing a deposition surface of a substrate; and

exhausting from a second position opposing the deposition surface.

(16) The atomic layer deposition method according to (15) above,

in which the first position and the second position are adjacent to each other.

(17) The atomic layer deposition method according to (15) or (16) above, further including:

supplying gas from a plurality of first positions; and

exhausting from a plurality of second positions.

(18) The atomic layer deposition method according to any one of (15) to (17) above, further including

supplying gas activated by plasma from the first position.

(19) The atomic layer deposition method according to (18), further including

causing plasma of the gas supplied from the first position by applying a voltage between the deposition surface and a surface opposing the deposition surface.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. An atomic layer deposition apparatus, comprising:
a sealable deposition chamber;
a holding portion configured to hold a substrate including a deposition surface in the deposition chamber;
a supply mechanism that includes an introduction portion connected to a gas supply source that supplies gas and is configured to supply gas introduced into the introduction portion to the deposition chamber from a position opposing the deposition surface; and
an exhaust mechanism that includes an exhaust portion connected to an exhaust mechanism capable of exhausting gas and is configured to exhaust the deposition chamber from a position opposing the deposition surface.

2. The atomic layer deposition apparatus according to claim 1,
wherein the supply mechanism further includes a supply port that is connected to the introduction portion and opposes the deposition surface, and
wherein the exhaust mechanism further includes an exhaust port that is connected to the exhaust portion and opposes the deposition surface.

3. The atomic layer deposition apparatus according to claim 2,
wherein the supply port and the exhaust port are adjacent to each other.

4. The atomic layer deposition apparatus according to claim 2,
wherein the supply mechanism further includes a plurality of supply ports and a supply path that connects the plurality of supply ports to the introduction portion and forms a manifold with the plurality of supply ports, and
wherein the exhaust mechanism further includes a plurality of exhaust ports and an exhaust path that connects the plurality of exhaust ports to the exhaust portion and forms a manifold with the plurality of exhaust ports.

5. The atomic layer deposition apparatus according to claim 4,
wherein the supply path, the supply ports, the exhaust path, and the exhaust ports are all formed on a single flow path formation member.

6. The atomic layer deposition apparatus according to claim 4, further comprising
a plurality of supply mechanisms,
wherein the plurality of supply mechanisms supply different types of gas to the deposition chamber.

7. The atomic layer deposition apparatus according to claim 4,
wherein the supply mechanism further includes a plurality of supply paths and an introduction chamber that connects the plurality of supply paths to the introduction portion and forms a manifold with the plurality of supply paths, and
wherein the exhaust mechanism further includes a plurality of exhaust paths and an exhaust chamber that connects the plurality of exhaust paths to the exhaust portion and forms a manifold with the plurality of exhaust paths.

8. The atomic layer deposition apparatus according to claim 7,
wherein the plurality of supply paths and the plurality of exhaust paths are arranged alternately.

9. The atomic layer deposition apparatus according to claim 1, further comprising
a bypass path that connects the exhaust mechanism and the introduction portion.

10. The atomic layer deposition apparatus according to claim 1, further comprising
a plasma unit that is provided between the gas supply source and the introduction portion and causes plasma of the gas to be introduced into the introduction portion.

11. The atomic layer deposition apparatus according to claim 1, further comprising
a pair of electrodes that are provided inside the deposition chamber and connected to a power supply to cause plasma of the gas in the deposition chamber.

12. The atomic layer deposition apparatus according to claim 11,
wherein the exhaust mechanism and the supply mechanism are both formed on a single flow path formation member, and
wherein the holding portion and the flow path formation member constitute the pair of electrodes.

13. The atomic layer deposition apparatus according to claim 1, further comprising
a plurality of atomic layer deposition units each including the deposition chamber, the holding portion, the supply mechanism, and the exhaust mechanism.

14. The atomic layer deposition apparatus according to claim 13,
wherein the plurality of atomic layer deposition units are laminated in a direction vertical to the deposition surface.

15. An atomic layer deposition method, comprising:
supplying gas from a first position opposing a deposition surface of a substrate; and
exhausting from a second position opposing the deposition surface.

16. The atomic layer deposition method according to claim 15,
wherein the first position and the second position are adjacent to each other.

17. The atomic layer deposition method according to claim 15, further comprising:
supplying gas from a plurality of first positions; and
exhausting from a plurality of second positions.

18. The atomic layer deposition method according to claim 15, further comprising
supplying gas activated by plasma from the first position.

19. The atomic layer deposition method according to claim 15, further comprising
causing plasma of the gas supplied from the first position by applying a voltage between the deposition surface and a surface opposing the deposition surface.
